(19) United States
(12) Patent Application Publication
(10) Pub. No.: US 2024/0371695 A1
(43) Pub. Date: Nov. 7, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chuan-Lan Lin, Chiayi City (TW); Yu-Ping Wang, Hsinchu City (TW); Chien-Ting Lin, Tainan City (TW); Chu-Fu Lin, Kaohsiung City (TW); Chun-Ting Yeh, Taipei City (TW); Chung-Hsing Kuo, Taipei City (TW)

(73) Assignee: UNITED MICROELECTRONICS CORP., Hsin-Chu City (TW)

(21) Appl. No.: 18/204,398

(22) Filed: Jun. 1, 2023

(30) Foreign Application Priority Data
May 3, 2023 (TW) 112116421

(51) Int. Cl. H01L 21/78; H01L 29/06

(52) U.S. Cl. CPC H01L 21/78; H01L 29/06

(57) ABSTRACT

A method for fabricating a semiconductor device includes the steps of first providing a wafer, forming a scribe line on a front side of the wafer, performing a plasma dicing process to dice the wafer along the scribe line without separating the wafer completely, performing a laminating process to form a tape on the front side of the wafer, performing a grinding process on a backside of the wafer, and then performing an expanding process to divide the wafer into chips.

### BACKGROUND OF THE INVENTION

### 1. Field of the Invention

The invention relates to a method for fabricating semiconductor device, and more particularly, to a method of using plasma dicing process to dice a wafer.

### 2. Description of the Prior Art

As technology advances, augmented reality (AR) and virtual reality (VR) applications also progresses rapidly and in a foreseen future, AR and VR applications will likely be applicable to our daily lives including various applications in the fields of education, logistics, medicine, and military.

Currently, AR and VR applications are commonly implemented by head-mounted displays. The head-mounted displays in most circumstances connect the display driver integrated circuits (DDICs) including high-voltage (HV) devices, medium-voltage (MV) devices, and/or low-voltage (LV) devices to a display module through extremely long wires or metal interconnections. This design is typically applied to larger scale products that not only consumes a great amount of space but also increases the difficulty for mounting the device. Hence, how to improve the current process for producing a display device suitable for both AR and VR environments has become an important task in this field.

### SUMMARY OF THE INVENTION

According to an embodiment of the present invention, a method for fabricating a semiconductor device includes the steps of first providing a wafer, forming a scribe line on a front side of the wafer, performing a plasma dicing process to dice the wafer along the scribe line without separating the wafer completely, performing a laminating process to form a tape on the front side of the wafer, performing a grinding process on a backside of the wafer, and then performing an expanding process to divide the wafer into chips.

According to another aspect of the present invention, a semiconductor device includes a chip obtained after a dicing process, in which the chip includes a first sidewall having a top portion and a bottom portion, the top portion includes a first profile, the bottom portion includes a second profile, and the first profile and the second profile are different.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a micro display device according to an embodiment of the present invention.

FIG. 6 illustrates a top view of a lower wafer after fabrication of bonding pads is completed according to an embodiment of the present invention.

FIG. 7 illustrates a cross-section view of a lower wafer after fabrication of bonding pads is completed according to an embodiment of the present invention.

FIG. 8 is a flow chart diagram illustrating the process and corresponding location when dicing a top wafer according to an embodiment of the present invention.

FIG. 9 illustrates cross-section views of dicing a top wafer according to an embodiment of the present invention.

FIG. 10 illustrates a structural view of a diced semiconductor chip according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

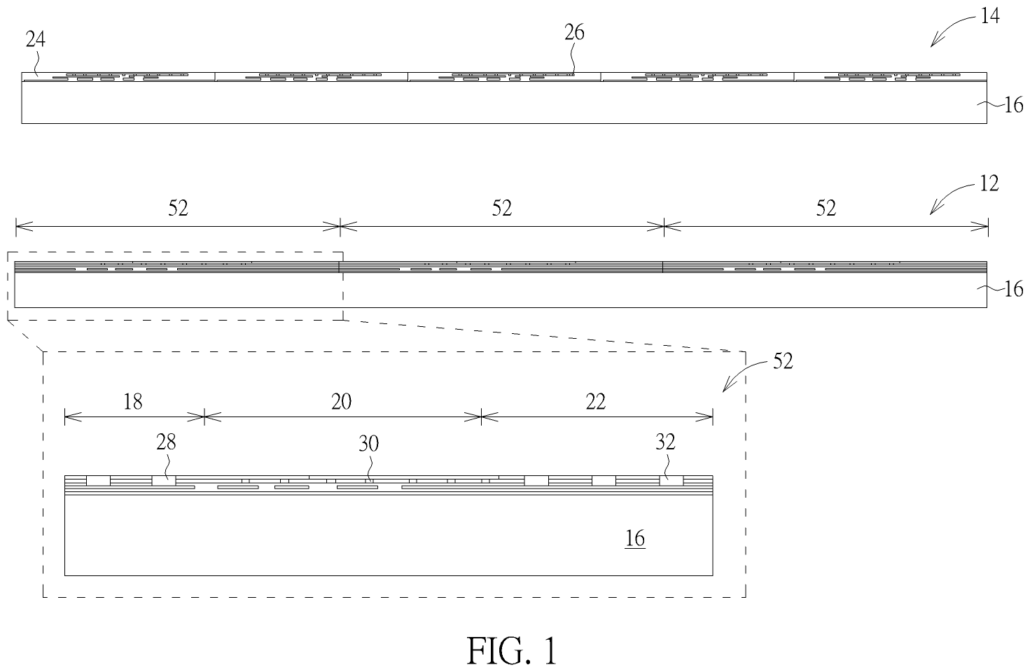

Referring to FIGS. 1-5, FIGS. 1-5 illustrate a method for fabricating a micro display device according to an embodiment of the present invention. As shown in FIG. 1, a wafer 12 and a wafer 14 both made of semiconductor material is provided, in which the wafer 12 includes MV devices, HV devices, and pixel circuits thereon while the wafer 14 includes LV devices for LV driving circuits and/or graphics process unit (GPU) thereon. Preferably, each of the wafers 12, 14 include a substrate 16 made of semiconductor materials as the substrate 12 could also be made of semiconductor substrate material including but not limited to for example silicon substrate, epitaxial silicon substrate, silicon carbide substrate or even a silicon-on-insulator (SOI) substrate, which are all within the scope of the present invention.

It should be noted that since the wafer 12 is typically used for supporting or connecting part of the LV devices and display modules after the wafer 14 is diced, hence a plurality of die regions 52 could be first defined on the wafer 12 so that after the other chips are bonded onto the wafer 12, the wafer 12 could then be diced according to each of the die regions 52. Preferably, the area or size of each of the die regions 52 is substantially greater than the size of the chip bonded afterwards and three regions including a first area 18, a second area 20, and a third area 22 are further defined on each of the die regions 52. Preferably, the first area 18 includes a bonding area used for connecting to external circuits, the second area 20 includes a chip to wafer area used for bonding to chips or dies obtained from dicing the wafer 14, and the third area 22 includes a micro-display area used for connecting to a micro display module.

In this embodiment, active devices and/or passive devices could be disposed on the wafers 12, 14, in which the active device could include metal-oxide semiconductor (MOS) transistor, oxide semiconductor field effect transistor (OS FET), fin field effect transistor (FinFET), or other active devices. If a MOS transistor were to be fabricated, the MOS transistor could include elements such as a gate structure on the substrate 16, a spacer (not shown) adjacent to the sidewalls of the gate structure, and a source/drain region in the substrate adjacent to two sides of the spacer, an interlayer dielectric (ILD) layer or inter-metal dielectric (IMD) layer 24 disposed on each of the MOS transistors, and metal interconnections 26 disposed in the ILD layer or IMD layer for connecting to each of the MOS transistors. Preferably, the devices or elements disposed on the wafer 12 are fabricated through a 65-80 nm technology node while the devices or elements disposed on the wafer 14 are fabricated through a 28-40 nm technology node.

At this stage or before other diced chips are bonded onto the wafer 12, a plurality of bonding pads 28, 30, 32 are disposed on each of the first area 18, the second area 20, and the third area 22 of the wafer 12 for connecting to the aforementioned active or passive devices. For achieving optimal connection with other devices in the later process, the bonding pads 28, 30, 32 disposed on the first area 18, the second area 20, and the third area 22 and the target elements connected to the bonding pads 28, 30, 32 afterwards could be made of same material or different materials while the bonding pads 28, 30, 32 themselves on the first area 18, the second area 20, and the third area 22 could also be made of same material or different materials.

For instance, the bonding pads 28 disposed on the first area 18 and the bonding pads 30 disposed on the second area 20 could be made of same material or different materials, the bonding pads 28 disposed on the first area 18 and the bonding pads 32 disposed on the third area 22 could be made of same material or different materials, and the bonding pads 30 disposed on the second area 20 and the bonding pads 32 disposed on the third area 22 could be made of same material or different materials. In this embodiment, since the bonding pads 28 disposed on the first area 18 are preferably used for connecting to external circuits, the bonding pads 28 are preferably made of low resistance material including but not limited to for example gold (Au). Moreover, the bonding pads 30 disposed on the second area 20 are preferably made of copper (Cu) and the bonding pads 32 disposed on the third area 22 preferably used for connecting to solder balls or bumps from a micro display module are preferably made of Cu or Al. It should be noted that in contrast to a plurality of bonding pads 28, 30, 32 have already been disposed on the first area 18, the second area 20, and the third area 22 of the wafer 12, no bonding pads are disposed on the wafer 14 at this stage except the aforementioned active devices and metal interconnections 26 connecting to the active devices.

In addition, the bonding pads 28, 30, 32 disposed on the first area 18, the second area 20, and the third area 22 also have different pitches, gaps, or spacing therebetween. For instance, the pitch or spacing between the bonding pads 28 on the first area 18 is preferably greater than the pitch or spacing between the bonding pads 30 on the second area 20 and the pitch or spacing between the bonding pads 28 on the first area 18 is also greater than the pitch or spacing between the bonding pads 32 on the third area 22. The pitch or spacing between the bonding pads 30 on the second area 20 on the other hand could be equal to or slightly less than the pitch or spacing between the bonding pads 32 on the third region 22. In this embodiment, the pitch or spacing between the bonding pads 28 on the first area 18 is preferably between 20-200 microns (μm), the pitch or spacing between the bonding pads 30 on the second area 20 is between 1-20 microns, and the pitch or spacing between the bonding pads 32 on the third area 22 is between 2-20 microns.

It should further be noted that the pitch or spacing between the bonding pads 28, 30, 32 on each area preferably refers to that all of the pitches or spacing between the bonding pads 28, 30, 32 on a certain area being less than or greater than the pitches or spacing between the bonding pads 28, 30, 32 on another area. For instance, the statement of the pitch or spacing between bonding pads 28 on the first area 18 being greater than the pitch or spacing between bonding pads 30 on the second area 20 and the pitch or spacing between bonding pads 32 on the third area 22 typically refers to that all of the pitches or spacing between bonding pads 28 on the first area 18 are greater than all of the pitches or spacing between bonding pads 30 on the second area 20 and all of the pitches or spacing between bonding pads 32 on the third area 22.

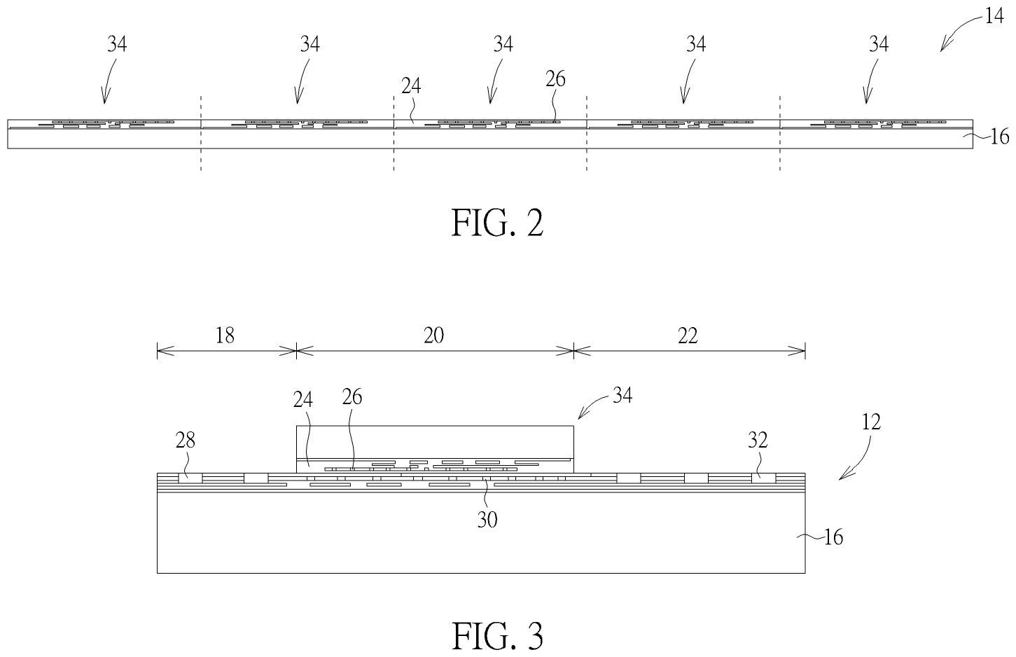

Next, as shown in FIG. 2, a thinning process is conducted to remove part of the substrate 16 of the wafer 14 thereby lowering the overall thickness of the wafer 14, and then a dicing process is conducted to dice the wafer 14 into a plurality of dies or chips 34.

Next, as shown in FIG. 3, the diced chip 34 is reversed and then a bonding process is conducted to bond the chip 34 carrying elements such as LV driving circuits and/or GPUs onto the un-diced wafer 12 carrying MV devices and HV devices. In this embodiment, the metal interconnections 26 on the chip 34 are preferably bonded to the bonding pads 30 on the second area 20 of the wafer 12 through a hybrid bonding approach, in which the metal interconnections 26 on the chip 34 are made of Cu while the bonding pads 30 on the second area 20 are also made of Cu. As such, the two elements 26 and 30 are directly connected or bonded with each other having front side facing front side through a hybrid bonding process.

Next, as shown in FIG. 4, a display module fabrication process is conducted to form a micro display 36 connected to the bonding pads 32 on the third area 22. In this embodiment, the micro display 36 could include various display device including but not limited to for example an organic light emitting diode (OLED) display, a mini light emitting diode display, or a micro light emitting diode display depending on the demand of the process or product and each of the micro displays 36 could further include color pixels 38 such as red, green, and blue.

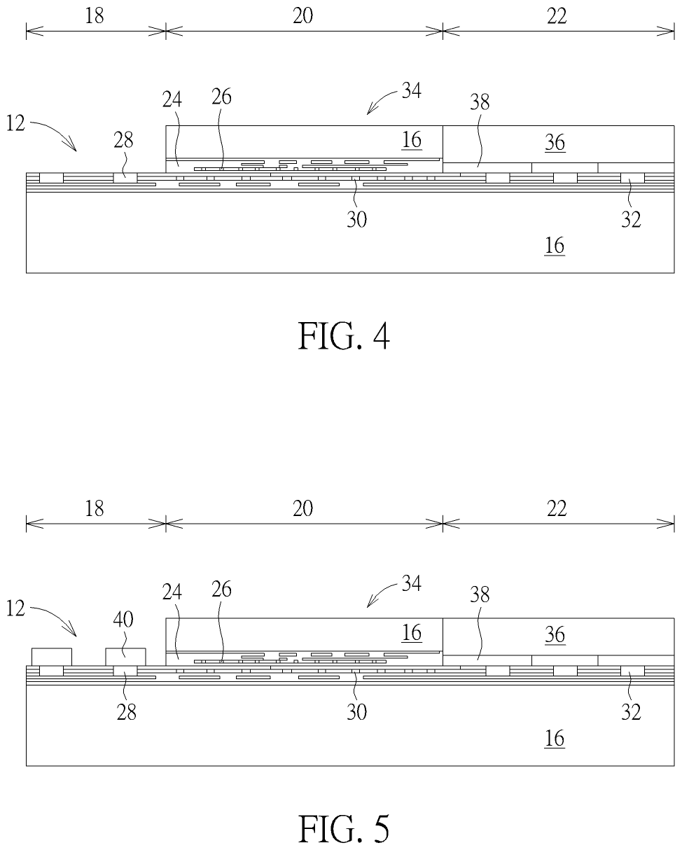

Next, as shown in FIG. 5, conductive wires such as wires 40 are formed to connect to the bonding pads 28 on the first area 18 of the wafer 12, and then the wafer 12 could be diced along the die regions 52 defined in the beginning into desirable dies or chips for later packaging process depending on the demand of the process. In this embodiment, the wires 40 used to connect to external circuits are preferably made of Cu while the bonding pads 28 on the first area 18 are preferably made of low resistance material such as Au. This completes the fabrication of a micro display device according to an embodiment of the present invention.

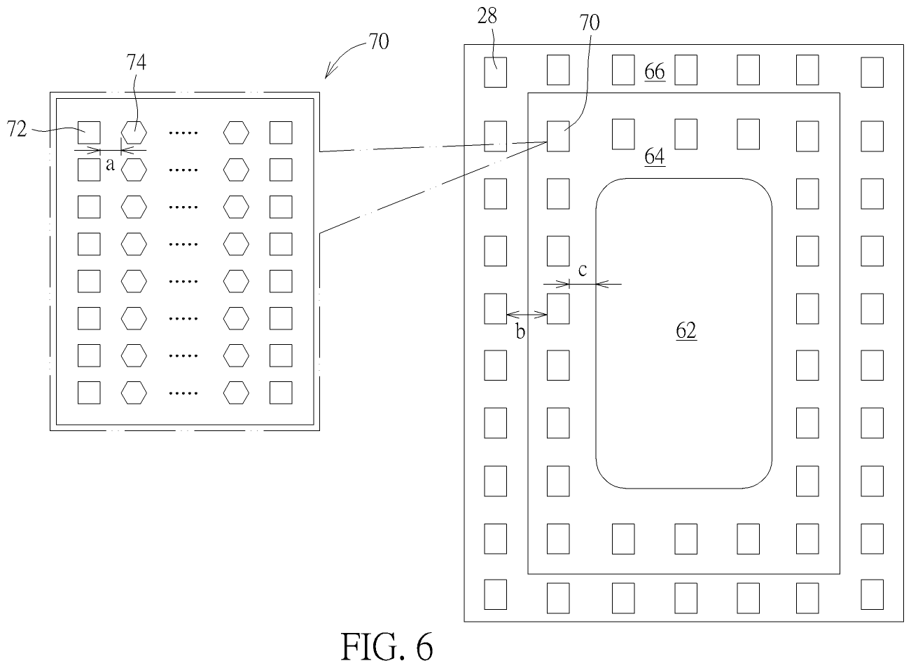

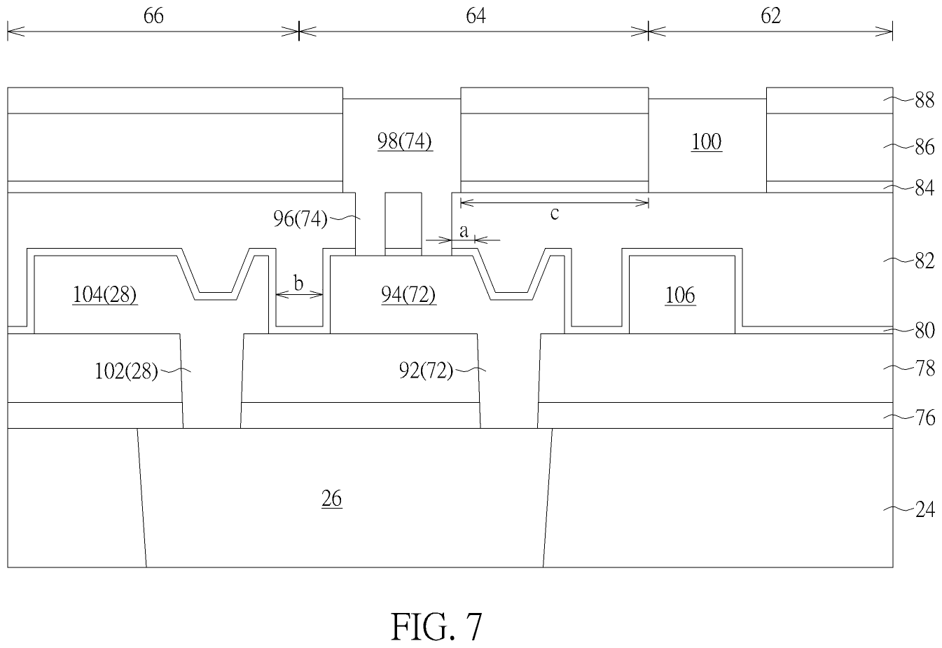

Referring to FIGS. 6-7, FIGS. 6-7 are top view and cross-section view of the bottom wafer after completing the fabrication of bonding pads according to the aforementioned embodiment, in which the right portion of FIG. 6 illustrates a top view of the overall bottom wafer and the left portion of FIG. 6 illustrates a top view of a sub-bonding area from the bonding area of the right portion. As shown in FIG. 6, the semiconductor device includes a circuit area 62 disposed on the substrate 16 or wafer 12, a bonding area 64 around the circuit area 62, and a pad area 66 or bonding pad area around the bonding area 64. Preferably, a plurality of bonding pads 28 are disposed on the pad area 66 on the right and the bonding area 64 further includes a plurality of sub-bonding areas 70 as each of the sub-bonding areas 70 further includes bonding pads 72 and 74 as shown on the left portion.

Preferably, the pad area 66 is in fact the first area 18 from the aforementioned embodiment and the bonding pads 28 are therefore the bonding pads 28 disposed on the first area 18, the bonding area 64 could be the second area 20 or third area 22 on the die region 52, and the bonding pads 72, 74 could be the bonding pads 30 on the second area 30 or the bonding pads 32 on the third area 22.

Specifically, the plurality of sub-bonding areas 70 are evenly distributed on the bonding area 64 and surrounding the circuit area 62, each of the sub-bonding areas 70 includes a rectangular shape under a top view, each of the sub-bonding areas 70 includes a plurality of bonding pads 72, 74, and the bonding pads 72, 74 are disposed on different levels. Preferably, the bonding pads 72 and the bonding pads 74 have different shapes under a top view perspective, in which each of the bonding pads 72 includes a square while each of the bonding pads 74 includes a hexagon.

In this embodiment, a distance a measured from an edge of the bonding pad 72 to an edge of the bonding pad 74 is preferably between 0-6 microns (μm) or most preferably at 3 microns. A distance b measured from an edge of the sub-bonding area 70 to an edge of the bonding pad 28 is preferably between 0-8 microns (μm) or most preferably at 4 microns, and a distance c between an edge of the sub-bonding area 70 to an edge of the circuit area 62 is preferably between 0-6 microns (μm) or most preferably at 3 microns.

As shown in FIG. 7, it would be desirable to follow the aforementioned processes to form active devices such as MOS transistors on a substrate 16 of the wafer 12, and then form multiple ILD layers or IMD layer 24 on the MOS transistors and metal interconnection 26 in the ILD layer or IMD layer 24 for electrically connecting the MOS transistors. In this embodiment, a plurality of dummy pads such as bonding pad 100 and metal routing 106 are disposed on the circuit area 62, bonding pads 72, 74 are disposed on the bonding area 64, and bonding pad 28 is disposed on the pad area 66, each of the bonding pads 28, 72, 74 are disposed on the active devices and connected to the metal interconnection 26, and upper level IMD layers disposed on the metal interconnection 26 and surrounding the bonding pads 28, 72, 74, 100 could include a stop layer 76, an IMD layer 78, a stop layer 80, an IMD layer 82, a stop layer 84, and IMD layer 86, and a stop layer 88.

Specifically, the metal interconnection 26 is extended from the bonding area 64 to the pad area 66 and the metal interconnection 26 is connected to the bonding pads 72, 74 on the bonding area 64 and the bonding pad 28 on the pad area 66 at the same time, in which the bonding pad 72 includes a bottom portion 92 connected to the metal interconnection 26 and a top portion 94 disposed on the bottom portion 92, the bonding pad 74 includes a bottom portion 96 connected to the top portion 94 of the bonding pad 72 and a top portion 98 disposed on the bottom portion 96, and the bonding pad 28 on the pad area 66 also includes a bottom portion 102 connected to the metal interconnection 26 and a top portion 104 disposed on the bottom portion 102.

Preferably, the top surface of the bottom portion 92 of the bonding pad 72 on the bonding area 64 is even with the top surface of the IMD layer 78 and the top surface of the bottom portion 102 of the bonding pad 28 on the pad area 66, the top surface of the top portion 94 of the bonding pad 72 on the bonding area 64 is even with the top surface of the top portion 104 of the bonding pad 28 on the pad area 66, the top surface of the bottom portion 96 of the bonding pad 74 on the bonding area 64 is even with the top surface of the IMD layer 82, and the top surface of the top portion 98 of the bonding pad 74 on the bonding area 64 is even with top surface of the bonding pad 100 on the circuit area 62. Moreover, the distance a measured from the left sidewall of the bottom portion 92 of the bonding pad 72 on the bonding area 64 to the right sidewall of the bottom portion 96 of the bonding pad 74 atop also shown in FIG. 6 previously is preferably between 0-6 microns or most preferably at 3 microns, the distance b measured between two sidewalls of the stop layer 80 on the bonding area 64 and the pad area 66 or from a left sidewall of the top portion 94 of the bonding pad 72 on the bonding area 64 to a right sidewall of the top portion 104 of the bonding pad 28 on the pad area 66 is between 0-8 microns or most preferably at 4 microns, and the distance c measured from the right sidewall of the top portion 98 of the bonding pad 74 on the bonding area 64 to the left sidewall of the bonding pad 100 on the circuit area 62 is between 0-6 microns or most preferably 3 microns.

Material wise, each of the bonding pads 28, 72, 74, 100 could further includes a barrier layer and a metal layer, in which the barrier layer could be selected from the group consisting of titanium (Ti), titanium nitride (TiN), tantalum (Ta), and tantalum nitride (TaN) and metal layer could be selected from the group consisting of tungsten (W), copper (Cu), aluminum (Al), titanium aluminide (TiAl), and cobalt tungsten phosphide (CoWP), but not limited thereto. In this embodiment, the bonding pads 28, 72 directly contacting the metal interconnection 26 are preferably made of same material such as aluminum (Al) while the bonding pads 74, 100 atop are made of copper (Cu). Nevertheless, according to other embodiment of the present invention the bonding pad 28 could also be made of gold (Au) as disclosed in the aforementioned embodiment. Moreover, the IMD layers 78, 82, 86 are preferably made of silicon oxide or ultra low-k (ULK) dielectric layer and the stop layers 76, 80, 84, 88 are preferably made of nitrogen doped carbide (NDC), silicon nitride, silicon carbon nitride (SiCN), or combination thereof.

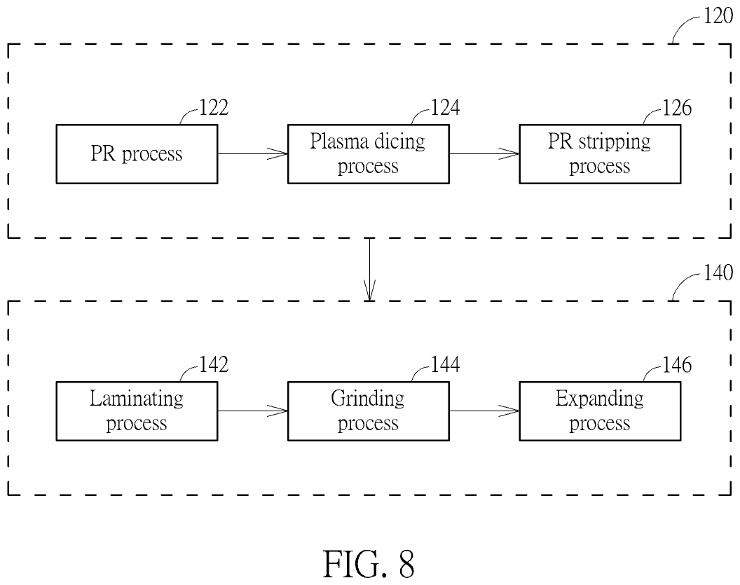

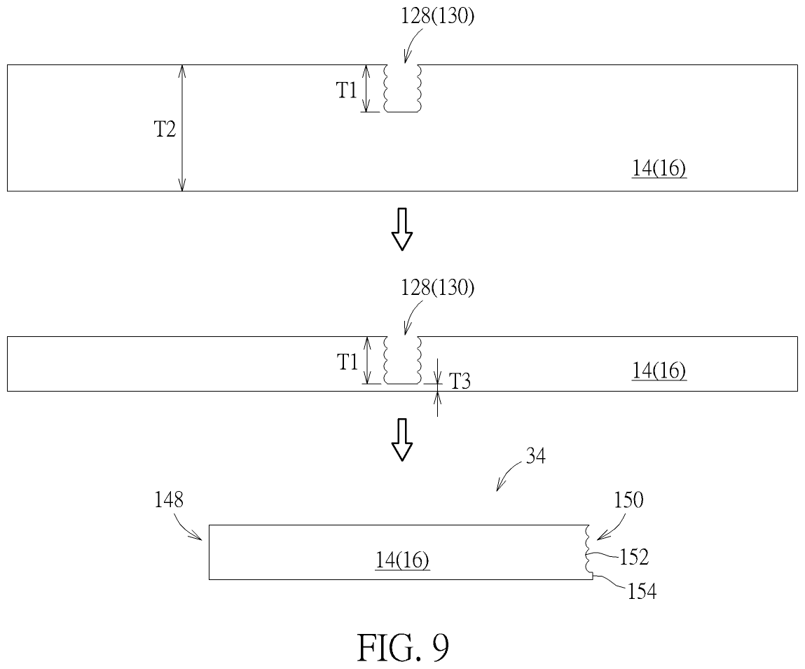

Referring to FIGS. 8-9, FIGS. 8-9 illustrate a method for dicing the wafer 14 as illustrated in FIGS. 1-2, in which FIG. 8 illustrates a flow chart diagram for dicing the wafer 14 and FIG. 9 illustrates a cross-section view of dicing and separating the wafer 14 according to an embodiment of the present invention. Typically, the fabrication process conducted in FIGS. 1-5 are carried out either in a fab or outsourced semiconductor assembly and test (OSAT) facilities. For instance, processes including forming active devices and bonding pads on the wafer 12 is usually completed in a fab while separating the wafer 14 and bonding with the wafer 12 are typically accomplished in OSAT facilities.

As shown on the top portion of FIG. 8, before conducting the process shown in FIG. 2 or after forming active and passive devices on the wafer 14 a series of fab processes 120 could be conducted by performing a patterned resist (PR) process 122 such as forming patterned resist on the wafer 14 for defining scribe lines, conducting a plasma dicing process 124 by using the patterned resist as mask through multiple etching processes to form a trench 130 or trenches serving as scribe lines 128 on the wafer 14, and then performing a patterned resist (PR) stripping process 126 for removing the patterned resist. It should be noted that even though the plasma dicing process 124 conducted at this stage removes multiple dielectric layers or passivation layers on the wafer 14 to form trenches, the dicing process only remove part of the wafer 14 or substrate 16 to form the trench 130 serving as scribe line 128 but does not separate the wafer 14 completely.

As shown in the top portion of FIG. 9, the depth T1 of the trench 130 formed in the wafer 14 at this stage is between 25-200 microns while the thickness T2 of the entire wafer 14 is approximately 700-800 microns or most preferably 750 microns. In other words, the depth of the trench 130 formed by the plasma dicing process 124 is preferably between 5-30% of the entire thickness of the original wafer 14. Moreover, since part of the substrate 16 of the wafer 14 is diced through plasma dicing or etching process to form the trench 130, the left and right sidewalls of the trench 130 preferably form scallop profiles during the dicing process while the bottom surface of the trench 130 still remains a planar surface.

Next, as shown in the bottom portion of FIG. 8, a series of OSAT process 140 is conducted at OSAT facilities by performing a laminating process 142 to form a tape on a front side of the wafer 14 for preventing the wafer 14 surface from contaminations in the later process, performing a grinding process 144 on the back side of the wafer 14 to remove part of the wafer 14, and then performing an expanding process 146 by using a wafer expander to divide the wafer 14 into multiple dies or chips 34.

As shown in the middle portion of FIG. 9, the grinding process 144 conducted at this stage preferably removes a major portion of the substrate 16 from the back side of the wafer 14 so that the remaining thickness of the wafer 14 measuring from the back side of the wafer 14 to the trench 130 is less than 1/10 of the original thickness of the wafer 14. In this embodiment, the thickness T3 of the remaining wafer 14 measuring from the back side of the wafer 14 to the trench 130 is preferably between 5-10 microns.

As shown in the bottom portion of FIG. 9, since the thickness T3 from the back side of the wafer 14 to the trench 130 is merely 1/100 or even less than 1/100 of the original thickness of the wafer 14, the expanding process 146 conducted thereafter could easily separate the wafer 14 along the scribe line 128 defined by the trench 130 into multiple dies or chips 34. Preferably, each of the divided dies or chips 34 includes a left sidewall 148 and a right sidewall 150, in which the left sidewall 148 includes a planar surface and the right sidewall 150 further includes a top portion 152 and a bottom portion 154. Specifically, the profile of the top portion 152 is different from the profile of the bottom portion 154. For instance, the top portion 152 includes a scallop shape surface or continuous wavy surface formed by multiple curves and the bottom portion 154 includes a completely flat or planar surface. Moreover, the thickness of the top portion 152 is preferably the same as the aforementioned depth T1 of the trench 130, the thickness of the bottom portion 154 is the same as the thickness T3, and the thickness of the bottom portion 154 is less than half of the thickness of the top portion 152. According to an embodiment of the present invention, the thickness of the bottom portion 154 could be 50%, 40%, 30%, 20%, 10%, 5%, or even less than 5% of the thickness of the top portion 152, which are all within the scope of the present invention.

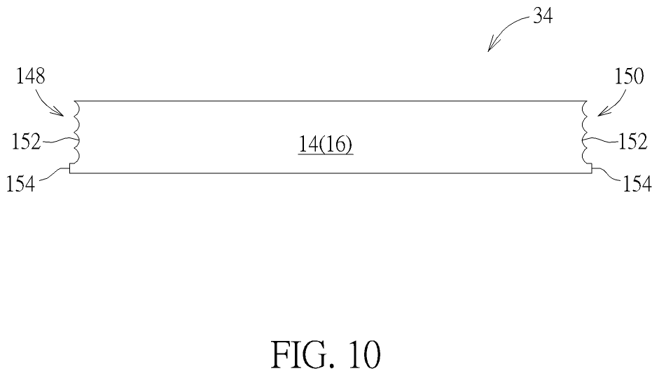

Referring to FIG. 10, FIG. 10 illustrates a structural view of a diced semiconductor chip according to an embodiment of the present invention. As shown in FIG. 10, in contrast to the chip 34 shown in FIG. 9 being located on the edge of the wafer 14 so that the left sidewall 148 and the right sidewall 150 of the diced chip 34 have different profiles, the chip 34 in this embodiment if situated in the relatively center of the wafer 14 before the dicing process, the left sidewall 148 and the right sidewall 150 of the chip 34 obtained after the dicing process would have same profile. Specifically, the diced die or chip 34 include a left sidewall 148 and a right sidewall 150, in which each of the left sidewall 148 and the right sidewall 150 further includes a top portion 152 and a bottom portion 154 and the profile of the top portion 152 is different from the profile of the bottom portion 154. For instance, the profile of the top portion 152 preferably includes a scallop shape surface formed by continuous wavy curves whereas the profile of the bottom portion 154 includes a completely flat or planar surface.

Overall, the present invention first conducts a plasma dicing process in the fab before transporting the wafers to OSAT facilities for carrying out grinding process and then completely separating the wafer into multiple chips. Preferably, the plasma dicing process could be accomplished by conducting multiple dry etching processes to remove part of the wafer along the scribe lines for forming trenches without separating the wafers completely. Next, the half-diced wafers are then transported to OSAT facilities for laminating process, grinding process, and expanding process and during the expanding process, the half-diced wafers are completely separated into a plurality of dies or chips. As disclosed in the aforementioned embodiment, at least one sidewall of each chip formed by plasma dicing process would include two different profiles. For instance, the top portion 152 of the sidewall of the chip could include scallop shape surface or a continuous wavy surface formed by multiple curves while the bottom portion 154 preferably includes a planar or completely flat surface. In contrast to using laser for dicing the wafer in conventional art, the utilization of plasma dicing process in this embodiment could minimize damage on edges of the chip, reduce blanket region remained on each scribe line, and obtain greater quantity of chips as the size of each chip and wafer is maintained the same.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a wafer;
forming a scribe line on a front side of the wafer;
performing a plasma dicing process to dice the wafer along the scribe line; and
performing a grinding process on a backside of the wafer.

2. The method of claim 1, further comprising:
performing a laminating process to form a tape on the front side of the wafer;
performing the grinding process; and
performing an expanding process to divide the wafer into chips.

3. The method of claim 2, further comprising:
performing the plasma dicing process to dice the wafer without separating the wafer completely; and
performing the expanding process to separate the wafer.

4. The method of claim 2, further comprising performing the laminating process in an outsource semiconductor assembly and test (OSAT) facility.

5. The method of claim 1, further comprising performing the grinding process in an OSAT facility.

6. The method of claim 1, further comprising performing the plasma dicing process in a fab.

7. A semiconductor device, comprising:
a chip obtained after a dicing process, wherein the chip comprises:
a first sidewall comprising a top portion and a bottom portion, wherein the top portion comprises a first profile, the bottom portion comprises a second profile, and the first profile and the second profile are different.

8. The semiconductor device of claim 7, wherein the first profile comprises a scallop shape surface.

9. The semiconductor device of claim 8, wherein the second profile comprises a planar surface.

10. The semiconductor device of claim 7, wherein the chip comprises a second sidewall comprising a top portion and a bottom portion, wherein the top portion comprises a third profile, the bottom portion comprises a fourth profile, and the third profile and the fourth profile are different.

11. The semiconductor device of claim 10, wherein the third profile comprises a scallop shape surface.

12. The semiconductor device of claim 11, wherein the fourth profile comprises a planar surface.
